(19) United States
(12) Patent Application Publication
(10) Pub. No.: US 2005/0079849 A1
(43) Pub. Date: Apr. 14, 2005

(54) Receiver for down-conversion of dual band for digital multimedia broadcasting or digital audio broadcasting

(76) Inventors: Yoo Sam Na, Seoul (KR); Won Jin Baek, Uiwang (KR); Ki Won Choi, Suwon (KR); Seung Won Seo, Choongjoo (KR); Seung Min Oh, Suwon (KR)

Correspondence Address: LOWE HAUPTMAN GILMAN & BERNER, LLP;Suite 310, 1700 Diagonal Road, Alexandria, VA, 22314, US

(21) Appl. No.: 10/791,850

(22) Filed: Mar. 4, 2004

(30) Foreign Application Priority Data
Oct. 10, 2003 (KR) 2003-70756

(51) Int. Cl. H03L 7/00; H04B 1/26; H04B 15/00

(52) U.S. Cl. 455/323; 455/313

(57) ABSTRACT

Disclosed herein is a receiver for down-conversion of a dual band. The receiver can down convert radio frequency signals of two different bands into a desired IF signal using only one voltage controlled oscillator (VCO), by dividing the output of the VCO into a predetermined ratio with a divider. The VCO outputs a desired oscillating frequency for conversion of the first-band RF signal into the IF signal, and the divider divides the desired oscillating frequency in a predetermined ratio to output a frequency for conversion of the second-band RF signal into the IF signal. Thus, the receiver can be formed on one silicon substrate.

### BACKGROUND OF THE INVENTION

1. Field of the Invention

The present invention relates to a receiver for converting a radio frequency (RF) signal for digital multimedia broadcasting (DMB) or digital audio broadcasting (DAB) into an intermediate frequency (IF) signal, and more particularly to a receiver for down-conversion of a dual band for DMB that is implemented in the form of an application specific integrated circuit (ASIC) chip by a complementary metal-oxide semiconductor (CMOS) process using a silicon process.

2. Description of the Related Art

FIG. 1 is a circuit diagram of a conventional two-chip heterodyne-type receiver, which is denoted by the reference numeral 100.

With reference to FIG. 1, the conventional two-chip heterodyne-type receiver 100 is operated in the following manner. First, a signal is received through an antenna 101 for an L-band (1452-1492 MHz), band pass filtered by a band pass filter (BPF) 102 which passes only L-band signal components, and then provided to an L-band processor 110 which is implemented in the form of a single IC chip. In the L-band processor 110, a low-noise amplifier (LNA) 111 amplifies only desired components of an output signal from the BPF 102 while suppressing the amplification of noise contained therein at the maximum, and then outputs the resulting signal to an automatic gain controller (AGC) 112. The AGC 112 automatically controls the gain of the output signal from the LNA 111 to provide its output signal which is always constant in level regardless of a level variation in the output signal from the LNA 111.

The output signal from the AGC 112 is provided to an image filter 113 which is arranged outside of the IC chip corresponding to the L-band processor 110. The image filter 113 removes image frequency components from the output signal from the AGC 112 and outputs the resulting signal to a mixer 114.

The mixer 114 mixes the output signal from the image filter 113 with a frequency signal from a voltage controlled oscillator (VCO) 115 to output a band_III (174-240 MHz) signal. The output signal from the mixer 114 is amplified by another LNA 116, band pass filtered by a BPF 122 and then provided to a band_III processor 130. Here, the VCO 115 is controlled by a phase locked loop (PLL)/I2C 117 and arranged separately outside of the L-band processor 110.

Thereafter, the signal received through the L-band antenna 101 is converted into a desired intermediate frequency (IF) signal through a processing operation of the band_III processor 130.

The operation of the band_III processor 130 will hereinafter be described. First, the signal provided from the L-band processor 110 or a signal received through a band_III antenna 121 is band pass filtered by the BPF 122, which passes only band_III signal components, and then provided to the band_III processor 130, which is implemented in the form of a single IC chip similarly to the L-band processor 110.

In the band_III processor 130, an output signal from the BPF 122 is provided to a mixer 134 via an LNA 131, an AGC 132, and an external BPF 133 for image removal. The mixer 134 mixes an output signal from the external BPF 133 with a frequency signal from a VCO 135. An output signal from the mixer 134 is converted into a desired IF signal through a buffer 136, another BPF 137, another AGC 138, and another BPF 139 for selection of a desired channel.

Here, the VCO 135 is controlled by a PLL/I2C 140 and arranged separately outside of the band_III processor 130. The above-mentioned conventional two-chip heterodyne-type receiver has a disadvantage in that the band_III processor 130 chip, as well as the L-band processor 110 chip, must be used together to process an L-band signal.

Further, the VCOs 115 and 135 must be provided separately external to the L-band processor 110 and band_III processor 130, respectively, resulting in an increase in manufacturing cost. Furthermore, the heterodyne-type receiver suffers a great deal of signal attenuation in the process of converting a received signal into an IF signal.

FIG. 2 is a circuit diagram of a conventional one-chip receiver for down-conversion of a dual band, which is denoted by the reference numeral 200.

With reference to FIG. 2, the conventional one-chip receiver 200 is able to process both an L-band signal and a band_III signal, as will hereinafter be described.

First, a signal is received through an L-band antenna 201 and provided through a first BPF 202 to an RF processor 230 which is implemented in the form of a single IC chip. In the RF processor 230, a first LNA 203 amplifies only desired components of an output signal from the first BPF 202 while suppressing the amplification of noise contained therein at the maximum, and then outputs the resulting signal to a first AGC 204. The first AGC 204 automatically controls the gain of the output signal from the first LNA 203 to provide its output signal which is always constant in level irrespective of a level variation in the output signal from the first LNA 203.

The output signal from the first AGC 204 is provided to a second BPF 205 for image removal which is arranged outside of the IC chip corresponding to the RF processor 230. The second BPF 205 removes image frequency components from the output signal from the first AGC 204 and outputs the resulting signal to a first mixer 206.

The first mixer 206 mixes the output signal from the second BPF 205 with a frequency signal from a first VCO 207 to output a band_III (174-240 MHz) signal. Here, the first VCO 207 is controlled by a PLL/I2C 213 and arranged outside of the IC chip corresponding to the RF processor 230.

The output signal from the first mixer 206 is inputted to a second mixer 211 through a second LNA 209, and a third BPF 210 for image removal.

The second mixer 211 mixes an output signal from the third BPF 210 with a frequency signal from a second VCO 212 to output a signal containing desired IF components. Here, the second VCO 212 is controlled by the PLL/I2C 213 and arranged inside of the IC chip corresponding to the RF processor 230.

The output signal from the second mixer 211 is provided via a fourth BPF 214, third LNA 215, fifth BPF 216 and second AGC 217 to a sixth BPF 218 for final channel selection, which then outputs an IF signal.

In the conventional one-chip receiver 200 for down-conversion of the dual band, a signal received through a band_III antenna 221 is inputted to the third BPF 210 via a seventh BPF 222 and fourth LNA 223 and then converted into an IF signal on the basis of the frequency signal from the second VCO 212.

However, in the above-mentioned conventional one-chip receiver 200 for down-conversion of the dual band, in order to process an L-band signal, the first VCO 207 must be provided outside of the IC chip corresponding to the RF processor 230 and the second VCO 212 must be provided separately inside of the IC chip. In particular, the provision of the first VCO 207 outside of the IC chip requires a great manufacturing cost. Further, the conventional one-chip receiver 200 suffers a great deal of signal attenuation, too, in that it processes a band_μm signal in a similar manner to the heterodyne-type receiver.

### SUMMARY OF THE INVENTION

Therefore, the present invention has been made in view of the above problems, and it is an object of the present invention to provide a receiver for down-conversion of a dual band which is capable of processing radio frequency signals of two different bands using one voltage controlled oscillator.

It is another object of the present invention to provide a receiver for down-conversion of a dual band wherein a filter for image removal is adapted to select a channel with respect to an input signal using a frequency signal from a voltage controlled oscillator, so as to guarantee high channel selectivity.

It is yet another object of the present invention to provide an optimized receiver for down-conversion of a dual band formed on one silicon substrate.

In accordance with an aspect of the present invention, the above and other objects can be accomplished by the provision of a receiver for down-conversion of a dual band, comprising: first amplification means for amplifying a radio frequency (RF) signal of a first band; second amplification means for amplifying an RF signal of a second band that is lower than the first band; a first filter connected to output terminals of the first and second amplification means, the first filter removing image frequency components from output signals from the first and second amplification means; a voltage controlled oscillator (VCO) for outputting a desired oscillating frequency for conversion of the first-band RF signal into an intermediate frequency (IF) signal; a divider for dividing the desired oscillating frequency in a predetermined ratio to output a frequency for conversion of the second-band RF signal into the IF signal; a mixer connected to output terminals of the first filter, VCO and divider, the mixer mixing the first-band RF signal with an output signal from the VCO or the second-band RF signal with an output signal from the divider to output the IF signal; and switching means for, when the first-band RF signal is processed, enabling the first amplification means and transferring the output signal from the VCO directly to the mixer, and, when the second-band RF signal is processed, enabling the second amplification means and transferring the output signal from the VCO to the mixer via the divider.

In accordance with another aspect of the present invention, there is provided a receiver for down-conversion of a dual band, comprising: first amplification means for amplifying an RF signal of a first band; a first filter connected to an output terminal of the first amplification means, the first filter removing image frequency components from an output signal from the first amplification means; a VCO for outputting a desired oscillating frequency for conversion of the first-band RF signal into an IF signal; a first mixer connected to output terminals of the first filter and VCO, the first mixer mixing an output signal from the first filter with an output signal from the VCO to output an RF signal of a second band that is lower than the first band; second amplification means for amplifying the second-band RF signal; a second filter connected to output terminals of the first mixer and second amplification means, the second filter removing image frequency components from output signals from the first mixer and second amplification means; a divider for dividing the desired oscillating frequency in a predetermined ratio to output a frequency for conversion of the second-band RF signal into the IF signal; a second mixer connected to output terminals of the second filter and divider, the second mixer mixing an output signal from the second filter with an output signal from the divider to output the IF signal; and switching means for, when the first-band RF signal is processed, enabling the first amplification means and transferring the output signal from the VCO directly to the first mixer, and, when the second-band RF signal is processed, enabling the second amplification means and transferring the output signal from the VCO to the second mixer via the divider.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a circuit diagram of a conventional two-chip heterodyne-type receiver;

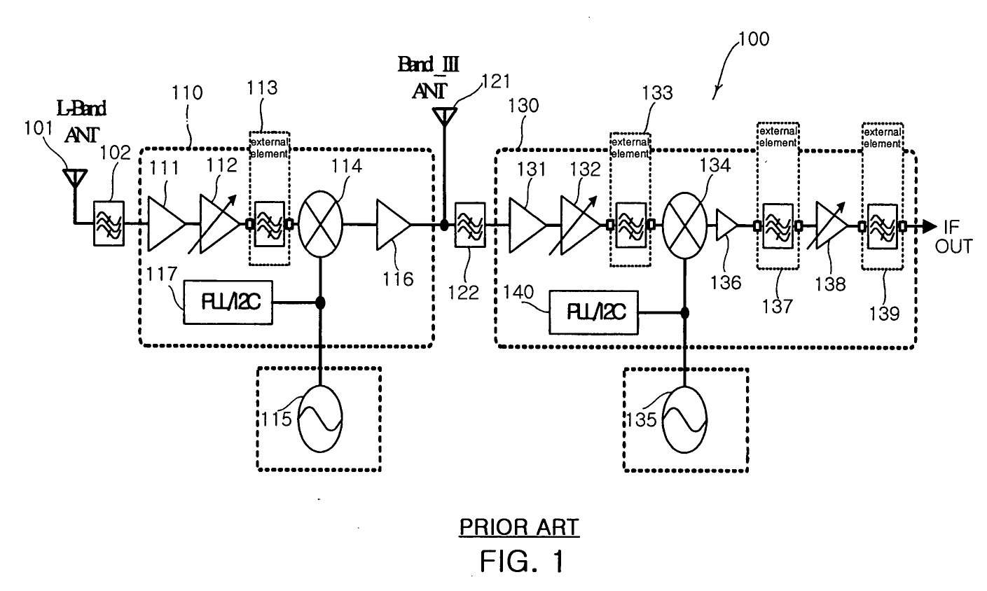

FIG. 2 is a circuit diagram of a conventional one-chip receiver for down-conversion of a dual band;

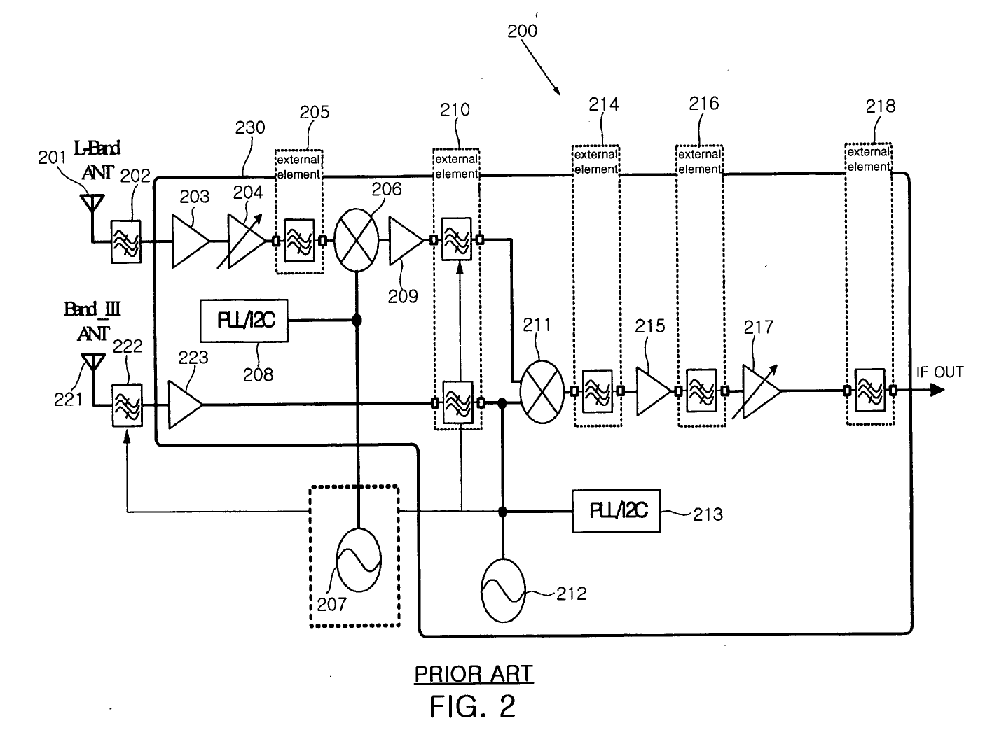

FIG. 3 is a circuit diagram of a receiver for down-conversion of a dual band for DMB according to a first embodiment of the present invention; and

FIG. 4 is a circuit diagram of a receiver for down-conversion of a dual band for DMB according to a second embodiment of the present invention.

### DESCRIPTION OF THE PREFERRED EMBODIMENTS

Now, preferred embodiments of the present invention will be described in detail with reference to the annexed drawings. In the drawings, the same or similar elements are denoted by the same reference numerals even though they are depicted in different drawings. In the following description of the present invention, a detailed description of known functions and configurations incorporated herein will be omitted when it may make the subject matter of the present invention rather unclear.

Embodiment 1

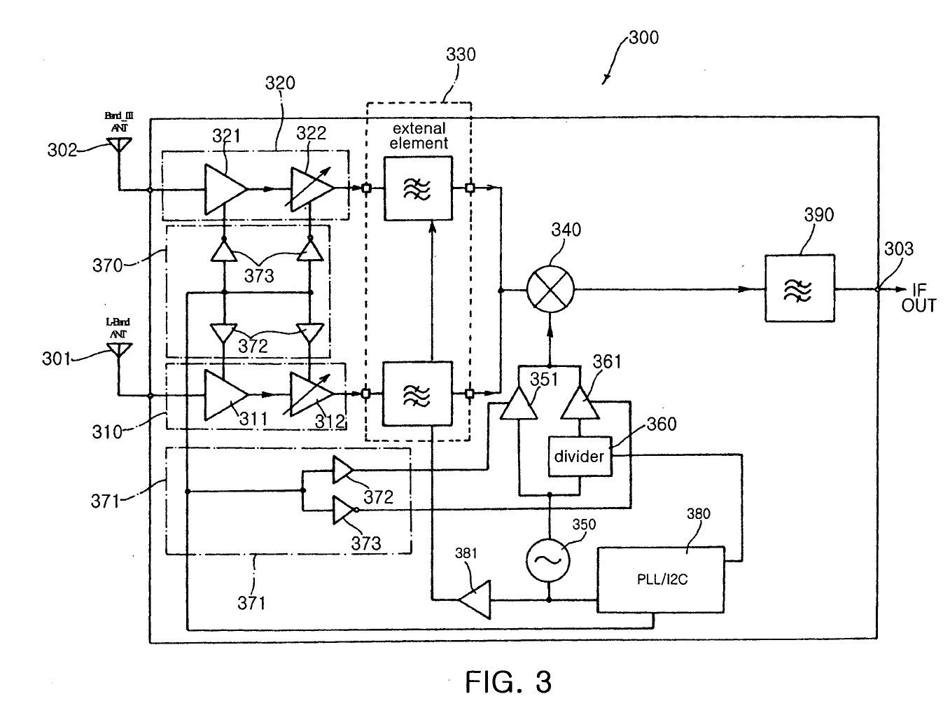

FIG. 3 is a circuit diagram of a receiver for down-conversion of a dual band according to a first embodiment of the present invention, which is denoted by the reference numeral 300.

With reference to FIG. 3, the receiver 300 for down-conversion of the dual band according to the first embodiment of the present invention comprises a first amplification circuit 310, a second amplification circuit 320, a first filter 330, a voltage controlled oscillator (VCO) 350, a divider 360, a mixer 340, and switching circuits 370 and 371. These components, except the first filter 330, are constructed in the form of one IC chip on a silicon substrate, as will hereinafter be described.

A radio frequency (RF) signal (referred to hereinafter as a ‘first-band RF signal’) received through an antenna 301 for an L-band (1452-1492 MHz) is provided to the first filter 330 through the first amplification circuit 310, which includes an LNA 311 and AGC 312.

An RF signal (referred to hereinafter as a ‘second-band RF signal’) received through an antenna 302 for a band_III (174-240 MHz) is provided to the first filter 330 through the second amplification circuit 320, which includes an LNA 321 and AGC 322 similarly to the first amplification circuit 310.

The first filter 330 has its output terminal connected to the mixer 340.

The VCO 350 has its output terminal connected to the mixer 340 via a first buffer 351. The output terminal of the VCO 350 is also connected to the divider 360, the output terminal of which is connected to the mixer 340 via a second buffer 361.

The switching circuit 370 has its output terminals connected respectively to the first amplification circuit 310 and second amplification circuit 320, and the switching circuit 371 has its output terminals connected respectively to the first and second buffers 351 and 361.

The first filter 330 is also connected to a PLL/I2C 380 via a third buffer 381. The VCO 350, divider 360 and switching circuits 370 and 371 also have their input terminals connected to the PLL/I2C 380.

The mixer 340 has its output terminal connected to an output terminal 303 of the receiver 300 via a second filter 390.

The receiver 300 for down-conversion of the dual band according to the first embodiment of the present invention is operated in the following manner.

First, an RF signal (first-band RF signal) received through the L-band antenna 301 is inputted to the first amplification circuit 310 and then amplified to a predetermined level thereby. The first amplification circuit 310 includes the LNA 311 and AGC 312. The LNA 311 amplifies only desired components of the first-band RF signal while suppressing the amplification of noise contained therein at the maximum, and then outputs the resulting signal to the AGC 312. The AGC 312 automatically controls the gain of the output signal from the LNA 311 to provide its output signal which is always constant in level regardless of a level variation in the output signal from the LNA 311. The output signal from the AGC 312 is provided to the first filter 330.

Also, an RF signal (second-band RF signal) received through the band_III antenna 302 is inputted to the second amplification circuit 320 and then amplified to a predetermined level thereby. The second amplification circuit 320 includes the LNA 321 and AGC 322 similarly to the first amplification circuit 310. The LNA 321 amplifies only desired components of the second-band RF signal while suppressing the amplification of noise contained therein at the maximum, and then outputs the resulting signal to the AGC 322. The AGC 322 automatically controls the gain of the output signal from the LNA 321 to provide its output signal which is always constant in level irrespective of a level variation in the output signal from the LNA 321. The output signal from the AGC 322 is provided to the first filter 330.

The first filter 330 is arranged outside of the receiver chip and positioned in front of the mixer 340 and is an image reject filter for removing image frequency components contained in an input RF signal. The first filter 330 functions to select a channel with respect to the input signal using a frequency signal from the VCO 350, so as to increase channel selectivity. The first filter 330 provides its output signal to the mixer 340.

The VCO 350 outputs a desired oscillating frequency (600-1500 MHz) based on a control voltage provided from the PLL/I2C 380. The oscillating frequency from the VCO 350 is set to such a value that its difference with the frequency of the first-band RF signal can be equal to a desired intermediate frequency (IF). The output frequency from the VCO 350 is supplied to the mixer 340 via the first buffer 351.

The divider 360 divides the oscillating frequency from the VCO 350 into about ¼ thereof (150-375 MHz). The divider 360 provides its output signal to the mixer 340 via the second buffer 361. That is, the output frequency from the VCO 350 is provided to the mixer 340 along two paths, one being a connection to the mixer 340 via the first buffer 351 and the other being a connection to the mixer 340 via the divider 360 and second buffer 361.

The mixer 340 mixes an RF signal inputted through the first filter 330 with a frequency signal inputted from the VCO 350 through the first buffer 351 or second buffer 361 to output a signal containing desired IF components.

The switching circuits 370 and 371 cooperate to, if the first-band RF signal is received through the L-band antenna 301, enable the first amplification circuit 310 and first buffer 351 and disable the second amplification circuit 320 and second buffer 361. In this case, therefore, the mixer 340 mixes the first-band RF signal with the desired oscillating frequency signal from the VCO 350 to output a desired IF signal.

On the other hand, in the case where the second-band RF signal is received through the band_III antenna 302, the switching circuits 370 and 371 cooperate to activate the second amplification circuit 320 and second buffer 361 and deactivate the first amplification circuit 310 and first buffer 351. In this case, as a result, the mixer 340 mixes the second-band RF signal with the output frequency signal from the divider 360 to output a desired IF signal.

The PLL/I2C 380 compares the phase of the oscillating frequency signal from the VCO 350, fed back thereto, with that of a predetermined reference signal and adjusts the frequency and phase of the oscillating frequency signal from the VCO 350 in accordance with the comparison result. The PLL/I2C 380 has channel information and can increase channel selectivity by controlling the VCO 350 and first filter 330 using the same control voltage.

The PLL/I2C 380 also controls the switching circuits 370 and 371. The switching circuits 370 and 371 include buffers 372 having their output terminals connected respectively to the LNA 311 and AGC 312 in the first amplification circuit 310 and the first buffer 351, and inverters 373 having their output terminals connected respectively to the LNA 321 and AGC 322 in the second amplification circuit 320 and the second buffer 361. The buffers 372 and inverters 373 have their input terminals connected in common to the PLL/I2C 380. In order to process the first-band RF signal, the PLL/I2C 380 provides a logic signal ‘1’ to the switching circuits 370 and 371 to activate the first amplification circuit 310 and first buffer 351 while deactivating the second amplification circuit 320 and second buffer 361. To the contrary, for the processing of the second-band RF signal, the PLL/I2C 380 provides a logic signal ‘0’ to the switching circuits 370 and 371 to enable the second amplification circuit 320 and second buffer 361 while deactivating the first amplification circuit 310 and first buffer 351.

The second filter 390 is connected between the output terminal of the mixer 340 and the output terminal 303 of the receiver 300. The second filter 390 is a band pass filter (BPF) for selecting only signal components of a desired channel from the output signal from the mixer 340. Preferably, the second filter 390 may be arranged external to the receiver IC chip using a surface acoustic wave (SAW) filter capable of passing only signal components of a desired frequency at a narrow bandwidth to enable accurate channel selection. More preferably, the second filter 390 for channel selection may be arranged inside of the receiver IC chip.

Embodiment 2

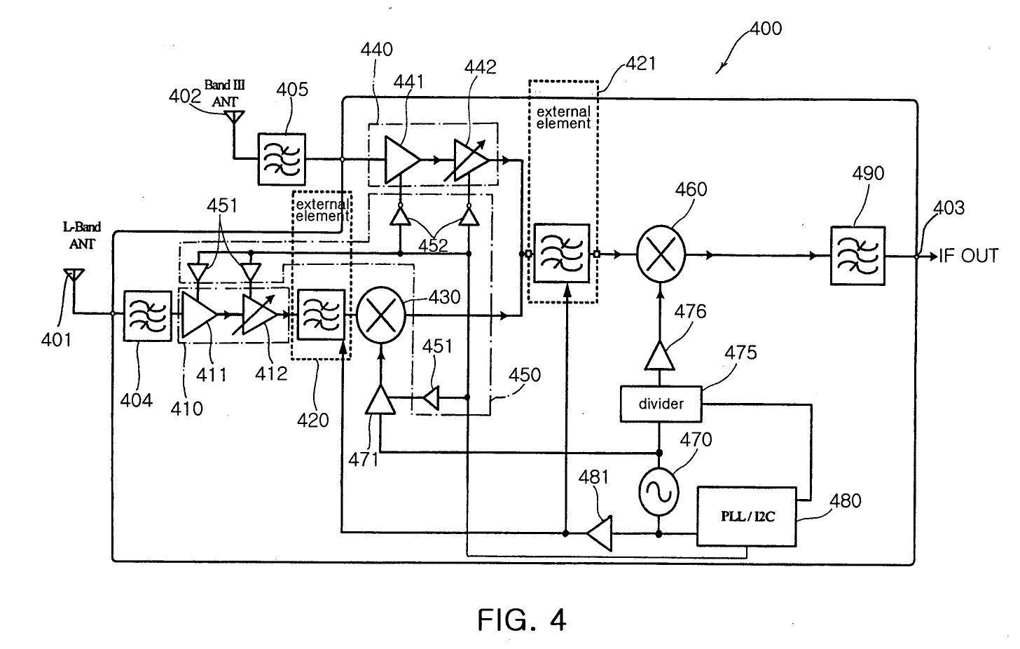

FIG. 4 is a circuit diagram of a receiver for down-conversion of a dual band according to a second embodiment of the present invention, which is denoted by the reference numeral 400.

With reference to FIG. 4, the receiver 400 for down-conversion of the dual band according to the second embodiment of the present invention comprises a L-band input filter 404, a band_III input filter 405, a first amplification circuit 410, a second amplification circuit 440, first to third filters 420, 421 and 490, a first mixer 430, a second mixer 460, a VCO 470, a divider 475 and a switching circuit 450. These components, except the band_III input filter 405, the first and second filters 420, 421, are constructed in the form of one IC chip on a silicon substrate, as will hereinafter be described.

An RF signal (first-band RF signal) received through an antenna. 401 for an L-band (1452-1492 MHz) is provided to the first amplification circuit 410 through the L-band input filter 404 arranged inside of the IC chip. The first amplification circuit 410 includes an LNA 411 and AGC 412.

The first amplification circuit 410 provides its output signal to the first filter 420, the output signal of which is inputted to the first mixer 430. The first mixer 430 provides its output signal to the second filter 421.

An RF signal (second-band RF signal) received through an antenna 402 for a band_III (174-240 MHz) is provided to the second filter 421 through the band_III input filter 405 arranged external to the IC chip and the second amplification circuit 440, which includes an LNA 441 and AGC 442 similarly to the first amplification circuit 410.

The second filter 421 has its output terminal connected to the second mixer 460.

The VCO 470 has its output terminal connected to the first mixer 430 via a first buffer 471. The output terminal of the VCO 470 is also connected to the divider 475, the output terminal of which is connected to the second mixer 460 via a second buffer 476.

The switching circuit 450 has its output terminals connected respectively to the first amplification circuit 410 and second amplification circuit 440.

The first filter 420 and second filter 421 have their input terminals connected in common to a PLL/I2C 480 via a third buffer 481. The VCO 470, divider 475 and switching circuit 450 also have their input terminals connected to the PLL/I2C 480.

The second mixer 460 has its output terminal connected to an output terminal 403 of the receiver 400 via a third filter 490.

The receiver 400 for down-conversion of the dual band according to the second embodiment of the present invention is operated in the following manner.

First, an RF signal (first-band RF signal) received through the L-band antenna 401 is inputted to the L-band input filter 404, which then passes only L-band signal components of the inputted RF signal to the first amplification circuit 410. The first amplification circuit 410 amplifies an output signal from the L-band input filter 404 to a predetermined level. To this end, the first amplification circuit 410 includes the LNA 411 and AGC 412. The LNA 411 amplifies only desired components of the output signal from the L-band input filter 404 while suppressing the amplification of noise contained therein at the maximum, and then outputs the resulting signal to the AGC 412. The AGC 412 automatically controls the gain of the output signal from the LNA 411 to provide its output signal which is always constant in level regardless of a level variation in the output signal from the LNA 411. The output signal from the AGC 412 is provided to the first filter 420.

The first filter 420 is arranged outside of the receiver chip and positioned in front of the first mixer 430 and is an image reject filter for removing image frequency components contained in an input RF signal. The first filter 420 provides its output signal to the first mixer 430.

The VCO 470 outputs a desired oscillating frequency (600-1500 MHz) based on a control voltage provided from the PLL/I2C 480. The oscillating frequency from the VCO 470 is set to such a value that its difference with the frequency of the first-band RF signal can belong to the band_III (174-240 MHz), or second RF band.

The output frequency from the VCO 470 is supplied to the first mixer 430 via the first buffer 471.

The first mixer 430 mixes an RF signal inputted through the first filter 420 with a frequency signal inputted from the VCO 470 through the first buffer 471 to output a signal containing band_III components. The first filter 420 functions to select a channel with respect to the input signal using the frequency signal from the VCO 470, so as to increase channel selectivity. The output signal from the first mixer 430 is inputted to the second filter 421.

Also, an RF signal (second-band RF signal) received through the band_III antenna 402 is inputted to the band_III input filter 405, which then passes only band_III components of the inputted RF signal to the second amplification circuit 440. The second amplification circuit 440 amplifies an output signal from the band_III input filter 405 to a predetermined level. To this end, the second amplification circuit 440 includes the LNA 441 and AGC 442 similarly to the first amplification circuit 410. The LNA 441 amplifies only desired components of the output signal from the band_III input filter 405 while suppressing the amplification of noise contained therein at the maximum, and then outputs the resulting signal to the AGC 442. The AGC 442 automatically controls the gain of the output signal from the LNA 441 to provide its output signal which is always constant in level regardless of a level variation in the output signal from the LNA 441. The output signal from the AGC 442 is provided to the second filter 421.

The second filter 421 is arranged outside of the receiver chip and positioned in front of the second mixer 460 and is an image reject filter for removing image frequency components contained in an input RF signal. The second filter 421 functions to select a channel with respect to the input signal using the frequency signal from the VCO 470, so as to increase channel selectivity.

The second filter 421 provides its output signal to the second mixer 460.

The divider 475 divides the oscillating frequency from the VCO 470 into about ¼ thereof (150-375 MHz). The divider 475 provides its output signal to the second mixer 460 via the second buffer 476.

The second mixer 460 mixes an RF signal inputted through the second filter 421 with the frequency signal inputted from the VCO 470 through the divider 475 and second buffer 476 to output a signal containing desired IF components.

The switching circuit 450 is adapted to, if a first-band RF signal is received through the L-band antenna 401, activate the first amplification circuit 410 and deactivate the second amplification circuit 440. In this case, therefore, the received first-band RF signal is converted into a second-band (band_III) RF signal through the first mixer 430 and, in turn, into an IF signal through the second mixer 460.

On the other hand, in the case where a second-band RF signal is received through the band_III antenna 402, the switching circuit 450 activates the second amplification circuit 440 and deactivates the first amplification circuit 410. In this case, as a result, the second mixer 460 extracts an IF signal using the received second-band RF signal.

The PLL/I2C 480 compares the phase of the oscillating frequency signal from the VCO 470, fed back thereto, with that of a predetermined reference signal and adjusts the frequency and phase of the oscillating frequency signal from the VCO 470 in accordance with the comparison result. The PLL/I2C 480 has channel information and can increase channel selectivity by controlling the VCO 470, first filter 420 and second filter 421 using the same control voltage.

The PLL/I2C 480 also controls the switching circuit 450. The switching circuit 450 includes buffers 451 having their output terminals connected respectively to the LNA 411 and AGC 412 in the first amplification circuit 410 and the first buffer 471, and inverters 452 having their output terminals connected respectively to the LNA 441 and AGC 442 in the second amplification circuit 440. The buffers 451 and inverters 452 have their input terminals connected in common to the PLL/I2C 480. In order to process the first-band RF signal, the PLL/I2C 480 provides a logic signal ‘1’ to the switching circuit 450 to enable the first amplification circuit 410 and first buffer 471 while deactivating the second amplification circuit 440. To the contrary, for the processing of the second-band RF signal, the PLL/I2C 480 provides a logic signal ‘0’ to the switching circuit 450 to activate the second amplification circuit 440 while disabling the first amplification circuit 410 and first buffer 471. At this time, the divider 475 is driven by a separate control signal from the PLL/I2C 480.

The L-band input filter 404 is arranged inside of the chip and between the L-band antenna 401 and the first amplification circuit 410. The L-band input filter 404 is a BPF for passing L-band signal components. The band_III input filter 405 is arranged outside of the chip and between the band_III antenna 402 and the second amplification circuit 440. The band_III input filter 405 is a BPF for passing band_III signal components.

The third filter 490 is connected between the output terminal of the second mixer 460 and the output terminal 403 of the receiver 400. The third filter 490 is a BPF for selecting only signal components of a desired channel from the output signal from the second mixer 460. Preferably, the third filter 490 may be arranged external to the receiver IC chip using a SAW filter capable of passing only signal components of a desired frequency at a narrow bandwidth to enable accurate channel selection. More preferably, the third filter 490 for channel selection may be arranged inside of the receiver IC chip.

As apparent from the above description, according to the present invention, a single conversion-type RF receiver is formed on one silicon substrate and a band_III signal and L-band signal of a DMB system are processed using one RF receiver IC chip which is implemented in a full CMOS technology. Therefore, the present invention has the effect of removing costs required for use of different processes and providing uniformity of design.

Further, according to the present invention, the same voltage and process as those of a baseband digital IC can be applied to the receiver, thereby increasing the possibility of implementing SoC (System-on-Chip).

Further, according to the present invention, a band_μm area can be driven using an oscillation range of an L-band VCO, thereby making it possible to process a dual-band signal with one VCO.

Further, according to the present invention, an external BPF for image removal is automatically controlled by means of a VCO inside of the chip, resulting in an increase in channel selectivity.

Further, according to the present invention, a simplified and optimized single-chip DMB receiver is provided to allow existing receiver application circuits employing the receiver to be simplified. Therefore, it is possible to configure all of many peripheral devices and application circuits for specific functions within a single semiconductor integrated circuit, resulting in a reduction in the number of mostly imported devices, more particularly the number of application devices in an RF receiver module amounting to about 30-40% of the receiver manufacturing cost. Consequently, the manufacturing cost can be reduced so as to make it easy to apply the receiver to a prospective competitive multimedia system.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A receiver for down-conversion of a dual band which converts a radio frequency (RF) signal of a first or second band into a desired intermediate frequency (IF) signal, said second band being lower than said first band, said receiver comprising:
first amplification means for amplifying said first-band RF signal;
second amplification means for amplifying said second-band RF signal;
a first filter connected to output terminals of said first and second amplification means, said first filter removing image frequency components from output signals from said first and second amplification means;
a voltage controlled oscillator (VCO) for outputting a desired oscillating frequency for the conversion of said first-band RF signal into said IF signal;
a divider for dividing said desired oscillating frequency in a predetermined ratio to output a frequency for the conversion of said second-band RF signal into said IF signal;
a mixer connected to output terminals of said first filter, VCO and divider, said mixer mixing said first-band RF signal with an output signal from said VCO or said second-band RF signal with an output signal from said divider to output said IF signal; and
switching means for, when said first-band RF signal is processed, enabling said first amplification means and transferring the output signal from said VCO directly to said mixer, and, when said second-band RF signal is processed, enabling said second amplification means and transferring the output signal from said VCO to said mixer via said divider.

2. The receiver as set forth in claim 1, further comprising a phase locked loop (PLL)/I2C for controlling said switching means.

3. The receiver as set forth in claim 2, wherein said PLL/I2C has channel information and serves to control said VCO and said first filter using the same control voltage.

4. The receiver as set forth in claim 1, further comprising a second filter for channel selection formed on an integrated circuit (IC) chip in such a manner that it is connected between an output terminal of said mixer and an output terminal of said receiver.

5. A receiver for down-conversion of a dual band which converts an RF signal of a first or second band into a desired IF signal, said second band being lower than said first band, said receiver comprising:
first amplification means for amplifying said first-band RF signal;
a first filter connected to an output terminal of said first amplification means, said first filter removing image frequency components from an output signal from said first amplification means;
a VCO for outputting a desired oscillating frequency for the conversion of said first-band RF signal into said IF signal;
a first mixer connected to output terminals of said first filter and VCO, said first mixer mixing an output signal from said first filter with an output signal from said VCO to output said second-band RF signal;
second amplification means for amplifying said second-band RF signal;
a second filter connected to output terminals of said first mixer and second amplification means, said second filter removing image frequency components from output signals from said first mixer and second amplification means;
a divider for dividing said desired oscillating frequency in a predetermined ratio to output a frequency for the conversion of said second-band RF signal into said IF signal;
a second mixer connected to output terminals of said second filter and divider, said second mixer mixing an output signal from said second filter with an output signal from said divider to output said IF signal; and
switching means for, when said first-band RF signal is processed, enabling said first amplification means and transferring the output signal from said VCO directly to said first mixer, and, when said second-band RF signal is processed, enabling said second amplification means and transferring the output signal from said VCO to said second mixer via said divider.

6. The receiver as set forth in claim 5, further comprising a PLL/I2C for controlling said switching means.

7. The receiver as set forth in claim 6, wherein said PLL/I2C has channel information and serves to control said VCO, said first filter and said second filter using the same control voltage.

8. The receiver as set forth in claim 5, further comprising a third filter for channel selection formed on an IC chip in such a manner that it is connected between an output terminal of said second mixer and an output terminal of said receiver.
